(19) United States
(12) Patent Application Publication
(10) Pub. No.: US 2025/0040410 A1
(43) Pub. Date: Jan. 30, 2025

(54) DISPLAY DEVICE AND MANUFACTURING METHOD OF DISPLAY DEVICE

(71) Applicant: Samsung Display Co., Ltd., Yongin-Si (KR)

(72) Inventors: Soo Dong KIM, Yongin-si (KR); Jung Hwan YI, Yongin-si (KR); Jongmin OK, Yongin-si (KR)

(21) Appl. No.: 18/406,229

(22) Filed: Jan. 8, 2024

(30) Foreign Application Priority Data
Jul. 26, 2023 (KR) 10-2023-0097755

(51) Int. Cl. H10K 59/80; H10K 59/12

(52) U.S. Cl. CPC H10K 59/877; H10K 59/1201

(57) ABSTRACT

A display device according to an embodiment includes a substrate including a first light emitting area, a second light emitting area, and a third light emitting area, a transistor disposed on the substrate, a light emitting element connected to the transistor, and an encapsulation layer disposed on the light emitting element, a partition wall disposed on the encapsulation layer, and a scattering layer disposed on the partition wall, wherein the scattering layer is continuously disposed on the entire surface of the substrate, and the scattering layer includes scatterers having different concentration in the first light emitting area, the second light emitting area, and the third light emitting area.

### CROSS-REFERENCE TO RELATED APPLICATION

This application claims priority to and the benefit of Korean Patent Application No. 10-2023-0097755 filed in the Korean Intellectual Property Office on Jul. 26, 2023, the entire contents of which are incorporated herein by reference.

### BACKGROUND

### (a) Field

The present disclosure relates to a display device and a manufacturing method of the display device.

### (b) Description of the Related Art

The display device is a device that visually displays images.

The display device is sometimes used as a display unit for a small product such as a mobile phone or the like, or a display unit for a large product such as a television.

The display device may include a plurality of pixels that receive electrical signals and emit light in order to display an image to the outside.

For a full-color display device, a plurality of pixels may emit light of different colors.

To this end, at least some of the plurality of pixels may have a filter unit that converts color.

Light of a first wavelength band generated from some pixels may be converted into light of a second wavelength band while passing through a corresponding filter unit, and the light of a second wavelength band may be extracted to the outside.

### SUMMARY

Embodiments are intended to provide a display device in which regions emitting light of different colors overlap scattering layers having different concentration of scatterers. Embodiments are also intended to provide a manufacturing method of a display device in which scattering layers continuously formed on the entire surface of a substrate have different concentration of scatterers for each region according to an emitted color.

The display device according to the present embodiment includes a substrate including a first light emitting area, a second light emitting area, and a third light emitting area, a transistor disposed on the substrate, a light emitting element connected to the transistor, an encapsulation layer disposed on the light emitting element, a partition wall disposed on the encapsulation layer, and a scattering layer disposed on the partition wall, the scattering layer is continuously disposed on an entire surface of the substrate, and the scattering layer includes scatterers of different concentration in the first light-emitting region, the second light emitting area, and the third light emitting area.

The substrate may further include a first non-light emitting area, a second non-light emitting area, and a third non-light emitting area.

The scattering layer may overlap the first non-light emitting area, the second non-light emitting area, and the third non-light emitting area, and may include scatterers having different concentration in each area.

A concentration of scatterers included in the scattering layer overlapping the first light emitting area is greater than that included in the scattering layer overlapping the second light emitting area, and the concentration of scatters included in the scattering layer overlapping the second light emitting area is greater than that included in the scattering layer overlapping the third light emitting area.

A concentration of the scatterers included in a scattering layer overlapping the first non-light emitting area is less that that included in a scattering layer overlapping the second non-light emitting area, and the concentration of the scatters in the scattering layer overlapping the second non-light emitting area is less than that included in ta scattering layer overlapping the third non-light emitting area.

The scattering layer may cover side surfaces and one surface of the partition wall and may fill an opening of the partition wall.

The display device further includes a color filter positioned on the scattering layer, the color filter comprising: a first color filter overlapping the first emitting area, a second color filter overlapping the second emitting area, and A third color filter overlapping the third light emitting area may be included.

The light emitting element emits white light, and the light emitting element may have a tandem structure.

A method of manufacturing a display device according to an embodiment includes forming a display unit on a front side of a substrate, forming a partition wall on the display unit, forming a scattering layer on the partition wall, and providing a temperature control unit on a rear surface of the substrate. and changing the temperature of the scattering layer through the temperature control unit, wherein scatterers are included in the scattering layer and the scatters move in the step of changing the temperature of the scattering layer.

The substrate may include a first light emitting area, a second light emitting area, and a third light emitting area.

The temperature control unit includes a first temperature controller overlapping the first light emitting area, a second temperature controller overlapping the second light emitting area, and a third temperature controller overlapping the third light emitting area. The first temperature controller, the second temperature controller, and the third temperature controller may have different temperatures.

The first temperature controller includes a first metal, the second temperature controller includes a second metal, the third temperature controller includes a third metal, and the first metal, the second metal, thermal conductivity of the first metal, the second metal, and the third metal may be different from one another.

The scattering layer overlapping the first temperature controller is heated to a first temperature, the scattering layer overlapping the second temperature controller is heated to a second temperature lower than the first temperature, and the scattering layer overlapping the third temperature controller may be heated to a third temperature lower than the second temperature.

A scatterer included in the scattering layer may move from a high-temperature area to a low-temperature area.

Amount of movement of the scatterers included in the scattering layer may increase as a temperature difference with an adjacent region increases.

The first temperature controller may include a first metal layer, the second temperature controller may include a second metal layer and a second insulating layer, and the third temperature controller may include a third metal layer and a third insulating layer.

A thickness of the first metal layer is greater than that of the second metal layer and the thickness of the second metal layer, and the thickness of the second metal layer is greater than that of the third metal layer. The first metal layer, the second metal layer, and the third metal layer may include the same metal.

A thickness of the second insulating layer is less than that of the third insulating layer.

The substrate includes a first non-light emitting area disposed adjacent to the first emitting area, a second non-light emitting area disposed adjacent to the second emitting area, and a third non-light emitting area disposed adjacent to the third emitting area, a first temperature controller overlapping the first non-light emitting area, a second temperature controller overlapping the second non-light emitting area, and a third temperature controller overlapping the third non-light emitting area, and the second temperature controller and the third temperature controller may have different temperatures.

The first temperature controller includes a first metal, the second temperature controller includes a second metal, the third temperature controller includes a third metal, and the first metal, the second metal and thermal conductivity of the first metal is greater than that of the second metal and the thermal conductivity of the second metal layer is greater than that of the third metal.

According to example embodiments, areas emitting light of different colors overlap scattering layers having different scatterer concentration, thereby reducing color deviation on the side surface of the display device.

A display device with improved display quality can be provided.

In addition, embodiments may provide a manufacturing method of a display device in which scattering layers continuously formed on the entire surface of a substrate have different concentration for each region according to the color of emitted light.

Even in a manufacturing process of a display device having a high resolution through the provision of a simplified process, occurrence of problems such as misplaced ink, ink mixing, and filling may be minimized.

### BRIEF DESCRIPTION OF THE DRAWINGS

FIG. 1 is an exploded perspective view of a display device according to an embodiment.

FIG. 2 is a schematic cross-sectional view of a display device according to an embodiment.

FIG. 3, FIG. 4, and FIG. 5 are schematic cross-sectional views of a display panel according to an embodiment.

FIG. 6, FIG. 7, FIG. 8, FIG. 9, and FIG. 10 each illustrate a method of manufacturing a display device according to an embodiment.

FIG. 11, FIG. 12, FIG. 13, and FIG. 14 are diagrams of a method of manufacturing a display device according to an embodiment.

FIG. 15 and FIG. 16 are diagrams of a manufacturing method of a display device according to an embodiment.

FIG. 17 and FIG. 18 are diagrams of a method of manufacturing a display device according to an embodiment.

FIG. 19A and FIG. 19B are schematic cross-sectional views of a display panel according to another embodiment.

FIG. 20, FIG. 21, FIG. 22, and FIG. 23 are diagrams of a method of manufacturing a display device according to another embodiment.

FIG. 24 and FIG. 25 are diagrams of a method of manufacturing a display device according to another embodiment.

FIGS. 26A, 26B, 26C and 26D are schematic cross-sectional views of a scatterer according to an embodiment.

FIG. 27 is an experimental image according to an embodiment.

### DETAILED DESCRIPTION OF THE EMBODIMENTS

Hereinafter, with reference to the accompanying drawings, various embodiments of the present inventive concept will be described in detail so that those skilled in the art can easily carry out the present inventive concept.

This inventive concept may be embodied in many different forms and is not limited to the embodiments set forth herein.

In order to clearly describe the present inventive concept, parts irrelevant to the description are omitted, and the same reference numerals are assigned to the same or similar components throughout the specification.

In addition, since the size and thickness of each component shown in the drawings are arbitrarily shown for convenience of explanation, the present inventive concept is not necessarily limited to that which is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, or plate is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being located above or below the reference part, and does not necessarily mean being located “above” or “on” it in the opposite direction of gravity.

In addition, throughout the specification, when a certain component is said to “include,” it means that it may further include other components without excluding other components unless otherwise stated.

Also, throughout the specification, when reference is made to a “planar image,” it means when the target part is viewed from above, and when reference is made to a “cross-sectional image,” it means when the cross-section of the target part cut vertically is viewed from the side.

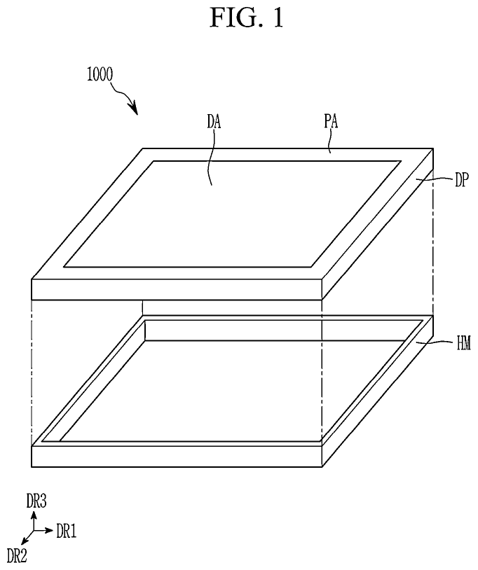

Hereinafter, a display device according to an embodiment will be described with reference to FIG. 1.

FIG. 1 is a schematic exploded perspective view of the display device according to an embodiment.

Referring to FIG. 1, the display device 1000 according to an embodiment may include a display panel DP and a housing HM.

One surface of the display panel DP on which an image is displayed is parallel to a surface defined by the first and second directions DR1 and DR2.

The normal direction of the surface where the image is displayed, that is, the thickness direction of the display panel DP, is indicated by the third direction DR3.

A front surface (or upper surface) and a rear surface (or lower surface) of each member are determined by the third direction DR3.

However, directions indicated by the first to third directions DR1, DR2, and DR3 are relative concepts, and may be converted into other directions.

The display panel DP may be a flat rigid display panel, but is not limited thereto and may also be a flexible display panel.

Meanwhile, the display panel DP may be formed of an organic light emitting display panel.

However, the type of display panel DP is not limited thereto, and may include various types of panels.

For example, the display panel DP may be formed of a liquid crystal display panel, an electrophoretic display panel, an electrowetting display panel, or the like.

Also, the display panel DP may be formed of a next-generation display panel such as a micro-light emitting diode display panel, a quantum dot light emitting diode display panel, and a quantum dot organic light emitting diode display panel.

A micro-light emitting diodes (LED) display panel is formed in such a way that each pixel includes light emitting diodes having a size of 10 micrometers to 100 micrometers.

Such a micro-LED display panel has advantages such as the use of inorganic materials, omission of a backlight, fast response speed, high luminance with low power consumption, and resistance to breaking when bent.

A quantum dot light emitting diode display panel is formed by attaching a film containing quantum dots or forming a material containing quantum dots.

Quantum dots include inorganic materials such as indium and cadmium, and refer to particles that emit light by themselves and have a diameter of several nanometers or less.

By adjusting the particle size of the quantum dots, light of a desired color can be displayed.

The quantum dot organic light emitting diode display panel uses a blue organic light emitting diode as a light source. In the quantum dot organic light emitting diode display panel, a film containing red and green quantum dots is attached on a substrate, or a material containing red and green quantum dots is deposited on a substrate to realize color.

The display panel DP according to an embodiment may include various other display panels.

As shown in FIG. 1, the display panel DP includes a display area DA where an image is displayed and a non-display area PA disposed adjacent to the display area DA. The non-display area PA is an area where an image is not displayed.

The display area DA may have a rectangular shape, for example, and the non-display area PA may have a shape surrounding the display area DA.

However, the shapes of the display area DA and the non-display area PA may be relatively designed without being limited thereto.

The housing HM provides a predetermined inner space.

The display panel DP is mounted inside the housing HM.

In addition to the display panel DP, various electronic components such as a power supply unit, a storage device, and an audio input/output module may be mounted inside the housing HM.

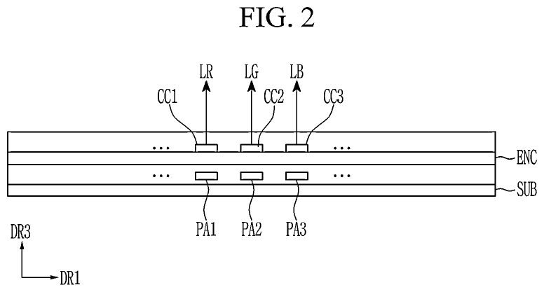

Hereinafter, a display area of a display panel according to an embodiment will be described with reference to FIG. 2.

FIG. 2 is a schematic cross-sectional view of a display panel according to an embodiment.

Referring to FIG. 2, a plurality of pixels PA1, PA2, and PA3 may be formed on the substrate SUB in an area corresponding to the display area DA of FIG. 1.

Each of the pixels PA1, PA2, and PA3 may include a plurality of transistors and light emitting elements connected thereto.

An encapsulation layer ENC may be positioned on the plurality of pixels PA1, PA2, and PA3.

The display area DA may be protected from outside air or moisture by the encapsulation layer ENC.

The encapsulation layer ENC may be integrally provided to overlap the entire surface of the display area DA, and may also be partially disposed on the non-display area PA.

A first color conversion unit CC1, a second color conversion unit CC2, and a third color conversion unit CC3 may be positioned on the encapsulation layer ENC.

The first color conversion unit CC1 overlaps the first pixel PA1, the second color conversion unit CC2 overlaps the second pixel PA2, and the third color conversion unit CC3 overlaps the third pixel PA3.

Light emitted from the first pixel PA1 may pass through the first color conversion unit CC1 to provide red light LR.

Light emitted from the second pixel PA2 may pass through the second color conversion unit CC2 to provide green light LG.

Light emitted from the third pixel PA3 may pass through the third color conversion unit CC3 to provide blue light LB.

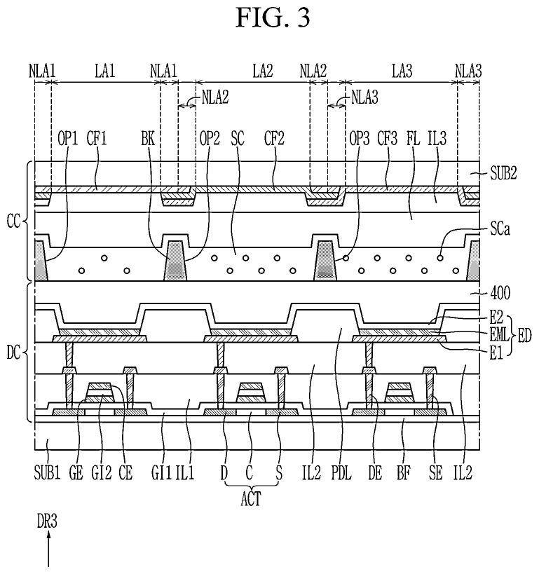

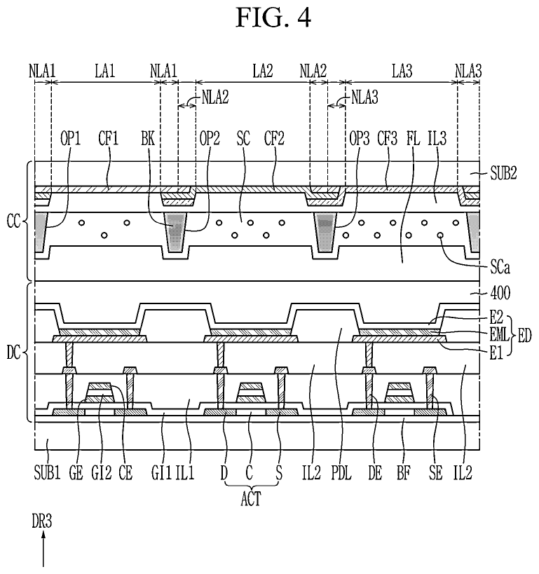

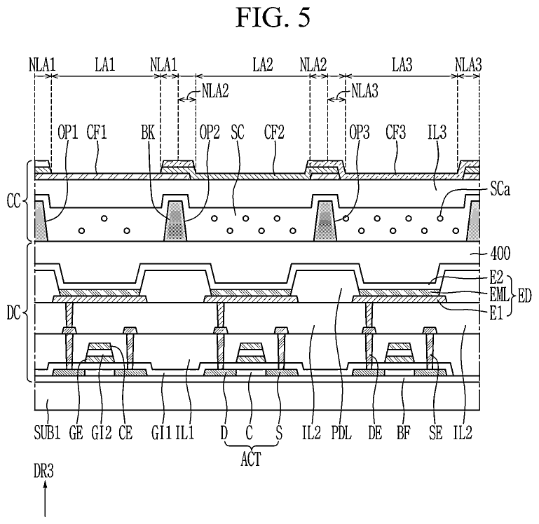

Hereinafter, a structure of a display panel according to an embodiment will be described in more detail with reference to FIG. 3.

FIG. 3 is a cross-sectional view of a display panel according to an embodiment.

First, referring to FIG. 3, the display area DA according to an embodiment includes a first light emitting area LA1 emitting red light, a second light emitting area LA2 emitting green light, and a third light emitting area LA3 emitting blue light.

Non-light emitting areas NLA1, NLA2, and NLA3 may be positioned between the first light emitting area LA1, the second light emitting area LA2, and the third light emitting area LA3.

Each of the light emitting areas LA1, LA2, and LA3 may correspond to a pixel.

For example, the first light emitting area LA1, the second light emitting area LA2, and the third light emitting area LA3 may correspond to a red pixel, a green pixel, and a blue pixel, respectively, but are not limited thereto.

A cross-sectional structure of the display area DA will be described below.

The display unit DC according to an embodiment includes a first substrate SUB1.

The first substrate SUB1 may include a flexible material such as plastic that can be easily bent, folded, or rolled.

A buffer layer BF may be positioned on the first substrate SUB1.

The buffer layer BF may include silicon nitride (SiNₓ), silicon oxide (SiO₂), or silicon nitride oxide.

The buffer layer BF is positioned between the first substrate SUB1 and a semiconductor layer ACT to block impurities from the first substrate SUB1 to the semiconductor layer ACT during a crystallization process of the semiconductor layer ACT to form polycrystalline silicon, thereby improving the characteristics of the polycrystalline silicon. Stress on the semiconductor layer ACT formed on the buffer layer BF may be relieved by planarizing the first substrate SUB1.

The semiconductor layer ACT is positioned on the buffer layer BF.

The semiconductor layer ACT may be formed of polycrystalline silicon or an oxide semiconductor.

The semiconductor layer ACT includes a channel region C, a source region S, and a drain region D.

The source region S and the drain region D are disposed on both sides of the channel region C, respectively.

The channel region C is an intrinsic semiconductor not doped with impurities, and the source region S and drain region D are semiconductors doped with conductive impurities.

The semiconductor layer ACT may be formed of an oxide semiconductor, and in this case, a separate protective layer (not shown) may be added to protect the oxide semiconductor material that is vulnerable to an external environment such as high temperature.

A first gate insulating layer GI1 is positioned on the semiconductor layer ACT.

The first gate insulating film GI1 may be a single layer or a multi-layer including at least one of silicon nitride (SiNₓ), silicon oxide (SiO₂), and silicon oxynitride (SiOₓN_{y}). A gate electrode GE is positioned on the first gate insulating layer GI1.

The gate electrode GE may be a single-layer or a multi-layer including at least one of metal layer among copper (Cu), a copper alloy, aluminum (Al), an aluminum alloy, molybdenum (Mo), and a molybdenum alloy is stacked.

A second gate insulating layer GI2 is positioned on the gate electrode GE and the first gate insulating layer GI1.

The second gate insulating film GI2 may be a single layer or a multi-layer including at least one of silicon nitride (SiNₓ), silicon oxide (SiO₂), and silicon nitride.

A capacitor electrode CE may be positioned on the second gate insulating layer GI2.

The capacitor electrode CE may overlap the gate electrode GE and form a capacitor with the gate electrode GE and the second gate insulating layer GI2 disposed therebetween.

An interlayer insulating layer IL1 is positioned on the capacitor electrode CE and the first gate insulating layer GI1.

The interlayer insulating layer IL1 may include silicon nitride (SiNₓ), silicon oxide (SiO₂), or silicon oxynitride (SiOₓN_{y}).

An opening exposing the source region S and the drain region D is positioned in the interlayer insulating layer IL1.

A source electrode SE and a drain electrode DE are positioned on the interlayer insulating layer IL1.

The source electrode SE and the drain electrode DE are electrically connected to the source region S and the drain region D of the semiconductor layer ACT through openings formed in the interlayer insulating layer IL1 and the first gate insulating layer GI1.

A passivation layer IL2 is positioned on the interlayer insulating layer IL1, the source electrode SE, and the drain electrode DE.

Since the passivation layer IL2 covers and flattens steps formed in the interlayer insulating layer IL1, the source electrode SE, and the drain electrode DE, the first electrode E1 may be formed without a step on the passivation layer IL2.

The passivation layer IL2 may be made of an organic material such as polyacrylate resin or polyimide resin, or a laminated film of an organic material and an inorganic material.

A first electrode E1 is positioned on the passivation layer IL2.

The first electrode E1 is connected to the drain electrode DE through the opening of the passivation layer IL2.

The driving transistor including the gate electrode GE, the semiconductor layer ACT, the source electrode SE, and the drain electrode DE is connected to the first electrode E1 to supply a driving current to the light emitting element ED.

In addition to the driving transistor shown in FIG. 3, the display device according to the present embodiment includes a switching transistor (not shown) connected to a data line and transmitting a data voltage in response to a scan signal and connected to a driving transistor and driven in response to a scan signal, and a compensation transistor (not shown) for compensating the threshold voltage of the transistor may be further included.

A pixel defining layer PDL may be positioned on the passivation layer IL2 and the first electrode E1. The pixel defining layer PDL may have a pixel opening exposing the first electrode E1 and defining an emission area.

The pixel opening may have a planar shape substantially similar to that of the first electrode E1 and may have a planar diamond shape or an octagonal shape similar to the diamond shape, but is not limited thereto and may have any shape such as a rectangle or a polygon.

The pixel defining layer PDL may include an organic material such as polyacrylate resin or polyimide resin or a silica-based inorganic material.

An emission layer EML is positioned in the pixel opening on the first electrode E1.

The light emitting layer EML may be formed of a low-molecular weight organic material or a high-molecular weight organic material such as poly 3,4-ethylenedioxythiophene (PEDOT).

In addition, the light emitting layer EML is disposed between a first functional layer which includes a hole injection layer (HIL) and a hole transporting layer (HTL) and a second functional layer which includes an electron transporting layer (ETL) and an electron injection layer (EIL). The light emitting layer EML may be a multi-layer including at least two layers.

Most of the light emitting layers EML may be located within the pixel opening, and may also be located on the side and/or above the pixel defining layer PDL according to embodiments.

A second electrode E2 is positioned on the light emitting layer EML.

The second electrode E2 may be positioned over a plurality of pixels, and may receive a common voltage through a common voltage transfer unit (not shown) disposed in the non-display area.

The first electrode E1, the light emitting layer EML, and the second electrode E2 may constitute the light emitting element ED.

Here, the first electrode E1 may be an anode that is a hole injection electrode, and the second electrode E2 may be a cathode that is an electron injection electrode.

However, the embodiment is not necessarily limited thereto, and the first electrode E1 may serve as a cathode and the second electrode E2 may serve as an anode according to a driving method of the organic light emitting display device.

Holes and electrons are injected into the light emitting layer EML from the first electrode E1 and the second electrode E2, respectively, and light emission occurs when an exciton, which is a combination of the injected holes and electrons, falls from an excited state to a ground state.

Meanwhile, the light emitting element ED according to an embodiment may include a plurality of light emitting units emitting different lights.

Each light emitting unit may include a light emitting layer, and adjacent light emitting layers may contact each other or may include an intermediate layer positioned between adjacent light emitting layers.

The first electrode E1 and the second electrode E2 described above may be disposed on a lower and an upper surfaces of each of the plurality of light emitting units.

At least one of the plurality of light emitting units may display the first color, and at least one of the others may display the second color.

The first color and the second color may be different.

For example, it may include a first light emitting unit EL1, a second light emitting unit EL2, a third light emitting unit EL3, and a fourth light emitting unit EL4 that independently emit either red light, green light, or blue light.

The light emitting element ED according to an embodiment may emit white light while having a tandem structure.

An encapsulation layer 400 is positioned on the second electrode E2.

The encapsulation layer 400 may cover not only the upper surface but also the side surfaces of the display layer including the light emitting element ED, thereby sealing the display layer.

Since the light emitting element is very vulnerable to moisture and oxygen, the encapsulation layer 400 seals the light emitting element to block the inflow of external moisture and oxygen.

The encapsulation layer 400 may include a plurality of layers, which may be formed of a composite film including both an inorganic film and an organic film. The encapsulation layer 400 may be a triple layer in which a first inorganic film, an organic film, and a second inorganic film are sequentially formed.

A color conversion unit CC is positioned on the encapsulation layer 400.

The color conversion unit CC includes a second substrate SUB2 overlapping the first substrate SUB1.

The second substrate SUB2 may include a flexible material such as plastic that can be easily bent, folded, or rolled.

The color conversion unit CC may include a partition wall BK positioned on the encapsulation layer 400.

The partition wall BK may include a first opening OP1, a second opening OP2, and a third opening OP3 disposed in areas corresponding to the pixel openings.

The sizes of the first opening OP1, the second opening OP2, and the third opening OP3 may be different or the same.

A scattering layer SC may be positioned on the partition wall BK.

The scattering layer SC may overlap the entire surface of the first substrate SUB1 or the second substrate SUB2.

The scattering layer SC may be positioned in the first opening OP1, the second opening OP2, and the third opening OP3.

The scattering layer SC may cover side surfaces and top surfaces of the partition wall BK.

The scattering layer SC may be continuously formed within the display area.

The scattering layer SC may include a polymer resin such as polyacrylate (PA), polyurethane (PU), polyethylene (PE), an epoxy-based compound, an ester-based compound, or a scatterer included in the polymer resin.

Depending on the embodiment, the scattering layer SC may include a photocuring agent or a thermal curing agent.

For example, the scattering layer SC may include hexamethylene diacrylate, tetraethylene glycol diacrylate, dipropylene glycol diacrylate, or tripropylene glycol diacrylate and the like, and the material may be included in an amount of 0.1 wt % to 99 wt % based on the total weight of the scattering layer (SC).

According to an embodiment, the ink forming the scattering layer SC may have a vapor pressure of 106 to 10-1 mmHg, a surface energy of 1 to 40 dyne/cm, and a viscosity of about 1 to 40 cps.

Alternatively, as another example, the scattering layer SC may be formed of an ink containing a binder containing an acryl group, a monomer, and a solvent.

The solvent may include at least one of PGMEA, DMA, CHA, DPMA, and hexane.

The ink may have a vapor pressure of 1 mmHg or less and a viscosity of 0.1 to 20 cps.

The scattering layer SC may include a plurality of scatterers SCa.

The scattering layer SC may include less than about 70 wt % of scatterers.

The diameter of each scatterer (SCa) may be about 50 nanometers to about 300 nanometers.

The scatterer SCa may be one or more selected from the group consisting of SiO₂, BaSO₄, Al₂O₃, ZnO, ZrO₂, and TiO₂.

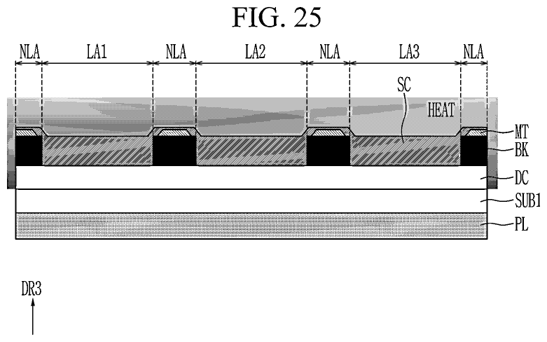

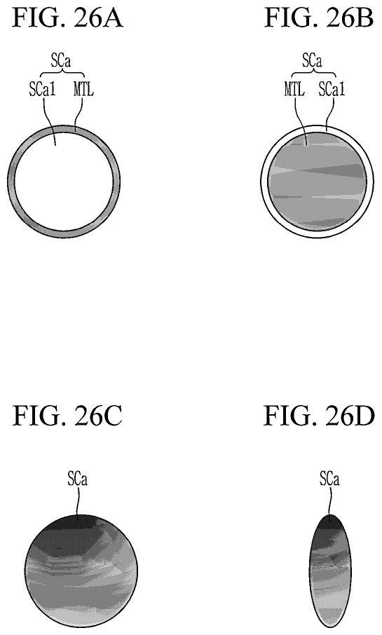

As an example, the scatterer SCa may include TiO₂, but is not limited thereto. The scatterer SCa is described in more detail with reference to FIG. 26.

The scattering layer SC may include a plurality of areas having different concentration of the scatterer SCa.

For example, the concentration of scatterers in the scattering layer SC overlapping the first light emitting area LA1, the scattering layer (SC) overlapping the second light emitting area LA2, and the scattering layer SC overlapping the third light emitting area LA3 may vary.

The content of scatterers included in the scattering layer SC overlapping the first light emitting area LA1 may be less than the content of scatterers included in the scattering layer SC overlapping the second light emitting area LA2.

In addition, the content of scatterers included in the scattering layer SC overlapping the second light emitting area LA2 may be less than the content of scatterers included in the scattering layer SC overlapping the third light emitting area LA3.

However, the present embodiment is not limited thereto, and the scattering layer SC may have various scatterer concentration according to regions.

Also, concentration of the scattering layer SC overlapping the non-light emitting areas NLA1, NLA2, and NLA3 may be different.

For example, the content of scatterers in the scattering layer SC overlapping the first non-light emitting area NLA1, the scattering layer SC overlapping the second non-light emitting area NLA2, and the scattering layer SC overlapping the third non-light emitting area NLA3 may be different.

The content of the scatterers included in the scattering layer SC that overlaps the first non-light emitting area NLA1 may be greater than the content of the scatterer included in the scattering layer SC that overlaps the second non-light emitting area NLA2.

Also, the content of the scatterers included in the scattering layer SC that overlaps the second non-light emitting area NLA2 may be greater than the content of the scatterer included in the scattering layer SC that overlaps the third non-light emitting area NLA3. However, the present embodiment is not limited thereto, and the scattering layer SC may have various concentration of the scatterers according to regions.

A filling layer FL may be positioned on the partition wall BK and the scattering layer SC.

The filling layer FL may combine components positioned on the first substrate SUB1 and components positioned on the second substrate SUB2.

One display panel may be formed through the filling layer FL.

The color conversion unit CC includes a first color filter CF1, a second color filter CF2, and a third color filter CF3 positioned between the second substrate SUB2 and a display unit DC.

The first color filter CF1 may overlap the first light emitting area LA1.

The first color filter CF1 can transmit red light emitted from a light emitting element ED overlapping the first light emitting area LA1, and absorb light of other wavelengths, increasing the purity of the red light emitted to the outside of the display device.

The second color filter CF2 may overlap the second light emitting area LA2.

The second color filter CF2 can transmit green light emitted from the light emitting element ED overlapping the second light emitting area LA2, and absorb light of other wavelengths, thereby increasing the purity of the green light emitted to the outside of the display device.

The third color filter CF3 may overlap the third light emitting area LA3.

The third color filter CF3 can transmit blue light emitted from the light emitting element ED overlapping the third light emitting area LA3, and absorb the light of the remaining wavelengths, thereby increasing the purity of the blue light emitted to the outside of the display device.

At least two of the first color filter CF1, the second color filter CF2, and the third color filter CF3 may overlap in the non-light emitting areas NLA1, NLA2, and NLA3 to serve as a light blocking layer.

The non-light emitting areas NLA1, NLA2, and NLA3 may overlap the pixel defining layer PDL of the display unit DC and the partition wall BK of the color conversion unit CC.

A third insulating layer IL3 may be positioned between the color filters CF1, CF2, and CF3, and the filling layer FL.

The third insulating layer IL3 may protect the color filters CF1, CF2, and CF3, and may include an organic material or an inorganic material.

The display unit DC according to an embodiment includes light emitting elements having a tandem structure, and white light is emitted from the light emitting elements.

In this case, each of the red, green, and blue pixels has a large change in lateral luminance, and the optimum scattering content of the scattering layer required for each pixel may be different.

The scattering layer SC according to an embodiment may include a plurality of regions having different concentration of scatterers while continuously overlapping the front surface of the first substrate SUB1 or the second substrate SUB2.

Even if the scattering layer is not patterned for each pixel, it is possible to provide different concentration of the scatterer required for each region.

Side luminance of the display device may be improved by providing scatterers having different densities depending on regions according to the color of emitted light.

Hereinafter, a display panel according to another embodiment will be described with reference to FIG. 4 and FIG. 5.

FIG. 4 and FIG. 5 are schematic cross-sectional views of a display panel according to another embodiment.

Descriptions of components identical to those described above will be omitted.

First, referring to FIG. 4, the color conversion unit CC may be positioned on the display unit DC.

The color conversion unit CC may include the second substrate SUB2 facing the first substrate SUB1.

The first color filter CF1, the second color filter CF2, and the third color filter CF3 may be positioned between the second substrate SUB2 and the display unit DC.

The third insulating layer IL3 may be positioned between the first color filter CF1, the second color filter CF2, and the third color filter CF3, and the display unit DC.

The third insulating layer IL3 may include an organic material or an inorganic material such as silicon nitride (SiNₓ), silicon oxide (SiO₂), or silicon oxynitride (SiOₓN_{y}).

The partition wall BK may be positioned between the third insulating layer IL3 and the display unit DC.

The partition wall BK may include a first opening OP1, a second opening OP2, and a third opening OP3 overlapping the pixel openings.

The sizes of the first opening OP1, the second opening OP2, and the third opening OP3 may be different or the same.

The scattering layer SC may be positioned between the partition wall BK and the display unit DC.

The scattering layer SC may overlap the entire surface of the first substrate SUB1 or the entire surface of the second substrate SUB2.

The scattering layer SC may continuously overlap the first substrate SUB1 or the second substrate SUB2.

The scattering layer SC covers one surface and a side surface of the partition wall BK facing the display unit DC, and may be positioned in the openings OP1, OP2, and OP3.

The scattering layer SC may include a plurality of scatterers SCa.

The scatterer SCa may be one or more selected from the group consisting of SiO₂, BaSO₄, Al₂O₃, ZnO, ZrO₂, and TiO₂.

The scattering layer SC may include a polymer resin and scatterers included in the polymer resin.

As an example, the scatterer SCa may include TiO₂, but is not limited thereto.

The scattering layer SC may include a plurality of areas having different concentration of the scatterer SCa.

For example, the scattering layer SC overlaps the first light emitting area LA1, the scattering layer SC overlaps the second light emitting area LA2, and the scattering layer SC overlaps the third light emitting area LA3. The scatter concentration can be different.

The content of scatterers included in the scattering layer SC overlapping the first emitting area LA1 may be less than the content of scatterers included in the scattering layer SC overlapping the second emitting area LA2.

In addition, the content of scatterers included in the scattering layer SC overlapping the second light emitting area LA2 may be less than the content of scatterers included in the scattering layer SC overlapping the third light emitting area LA3.

However, the present embodiment is not limited thereto, and the scattering layer SC may have various scattering concentration according to regions.

Also, concentration of the scattering layer SC overlapping the non-light emitting areas NLA1, NLA2, and NLA3 may be different.

For example, the content of scatterers in the scattering layer (SC) overlapping the first non-light emitting area (NLA1), the scattering layer (SC) overlapping the second non-light emitting area (NLA2), and the scattering layer (SC) overlapping the third non-light emitting area (NLA3) may be different.

The content of scatterers included in the scattering layer SC overlapping the first non-light emitting area NLA1 may be greater than the content of scatterers included in the scattering layer SC overlapping the second non-light emitting area NLA2.

In addition, the content of scatterers included in the scattering layer SC overlapping the second non-light emitting area NLA2 may be greater than the content of scatterers included in the scattering layer SC overlapping the third non-light emitting area NLA3.

However, the present embodiment is not limited thereto, and the scattering layer SC may have various scattering concentration according to regions.

The filling layer FL may be positioned between the scattering layer SC and the display unit DC.

The filling layer FL may combine the display unit DC and the color conversion unit CC.

Referring to FIG. 5, a display device according to an embodiment may include a display unit DC and a color conversion unit CC.

Since the display unit DC is the same as described with reference to FIG. 3, a description thereof will be omitted.

The color conversion unit CC includes the partition wall BK positioned on the display unit DC.

The partition wall BK may be positioned on the encapsulation layer 400 of the display unit DC.

The partition wall BK may include a first opening OP1, a second opening OP2, and a third opening OP3 overlapping the pixel openings.

The sizes of the first opening OP1, the second opening OP2, and the third opening OP3 may be different or the same.

The scattering layer SC may be positioned on the partition wall BK and the display unit DC.

The scattering layer SC may overlap the entire surface of the first substrate SUB1 or the entire surface of the second substrate SUB2.

The scattering layer SC may continuously overlap the first substrate SUB1 or the second substrate SUB2.

The scattering layer SC may cover the top and side surfaces of the partition wall BK, and may be positioned in the openings OP1, OP2, and OP3.

The scattering layer SC may include a plurality of scatterers SCa.

The scattering layer SC may include a polymer resin and scatterers included in the polymer resin.

The scatterer SCa may be one or more selected from the group consisting of SiO₂, BaSO₄, Al₂O₃, ZnO, ZrO₂, and TiO₂.

For example, the scatterer (SCa) may include TiO₂, but is not limited thereto.

The scattering layer SC may include a plurality of areas having different concentration of the scatterer SCa.

For example, the scattering layer SC overlaps the first light emitting area LA1, the scattering layer SC overlaps the second light emitting area LA2, and the scattering layer SC overlaps the third light emitting area LA3. Concentration of scatterers included may be different.

The content of scatterers included in the scattering layer SC overlapping the first emitting area LA1 may be less than the content of scatterers included in the scattering layer SC overlapping the second light emitting area LA2.

In addition, the content of scatterers included in the scattering layer SC overlapping the second light emitting area LA2 may be less than the content of scatterers included in the scattering layer SC overlapping the third light emitting area LA3.

However, the present embodiment is not limited thereto, and the scattering layer SC may have various scattering concentration according to regions.

Also, concentration of the scattering layer SC overlapping the non-light emitting areas NLA1, NLA2, and NLA3 may be different.

For example, the content of scatterers in the scattering layer SC overlapping the first non-light emitting area NLA1, the scattering layer SC overlapping the second non-light emitting area NLA2, and the scattering layer SC overlapping the third non-light emitting area NLA3 may be different.

The content of the scatterers included in the scattering layer SC overlapping the first non-light emitting area NLA1 may be greater than the content of the scatterer included in the scattering layer SC overlapping the second non-light emitting area NLA2.

In addition, the content of scatterers included in the scattering layer SC overlapping the second non-light emitting area NLA2 may be greater than the content of scatterers included in the scattering layer SC overlapping the third non-light emitting area NLA3.

However, the present embodiment is not limited thereto, and the scattering layer SC may have various scattering concentration according to regions.

The third insulating layer IL3 may be positioned on the scattering layer SC.

The third insulating layer IL3 may cover the entire surface of the scattering layer SC.

The third insulating layer IL3 may include an organic material or an inorganic material such as silicon nitride (SiNₓ), silicon oxide (SiO₂), or silicon oxynitride (SiOₓN_{y}).

Color filters CF1, CF2, and CF3 may be positioned on the third insulating layer IL3.

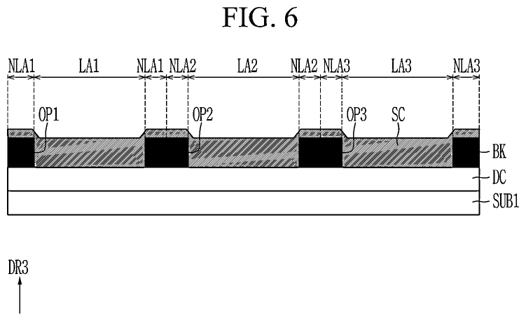

Hereinafter, a method of manufacturing a display device according to an embodiment will be described with reference to FIG. 6 to FIG. 10.

FIG. 6, FIG. 7, FIG. 8, FIG. 9, and FIG. 10 each illustrate a method of manufacturing a display device according to an embodiment.

Descriptions of components identical to those described above will be omitted.

Referring first to FIG. 6, in the method of manufacturing a display device according to an embodiment, a display unit DC is formed on a first substrate SUB1.

The display unit DC may have the stacked structure previously described with reference to FIG. 3, and a detailed description thereof will be omitted below.

The partition wall (BK) is formed on the display unit (DC).

The partition wall BK may include a first opening OP1, a second opening OP2, and a third opening OP3 overlapping the pixel openings, respectively.

The sizes of the first opening OP1, the second opening OP2, and the third opening OP3 may be different or the same.

The manufacturing method of the display device according to an embodiment has been described as an embodiment in which the partition wall BK is formed on the display unit DC, but is not limited thereto, and the partition wall BK is disposed based on the structure of FIG. 3 to FIG. 5 The location can be variously changed.

The scattering layer SC including scatterers is formed on the partition wall BK.

The scattering layer SC may be formed on the entire surface of the first substrate SUB1.

The scattering layer SC may cover the top and side surfaces of the partition wall BK and fill each of the openings OP1, OP2, and OP3.

The scattering layer SC may be formed through a coating process, an inkjet process, or a photolithography process.

A method of forming the scattering layer SC may not be limited.

The initially formed scattering layer SC may have substantially the same content of scatterers over the entire surface of the first substrate SUB1.

As shown in FIG. 7, a temperature control unit TU is provided on the rear surface of the first substrate SUB1.

The temperature control unit TU may include a first temperature controller TU1, a second temperature controller TU2, a third temperature controller TU3, and a plate PL.

The plate PL may heat or cool the first temperature controller TU1, the second temperature controller TU2, and the third temperature controller TU3.

The plate PL may heat or cool the first temperature controller TU1, the second temperature controller TU2, and the third temperature controller TU3 to a predetermined temperature.

The plate PL may include a heater or a cooler, but is not limited thereto.

The first temperature controller TU1, the second temperature controller TU2, and the third temperature controller TU3 may have different temperatures or have the same temperature.

For example, the first temperature controller TU1, the second temperature controller TU2, and the third temperature controller TU3 may directly contact the first substrate SUB1 and may have a higher temperature than the first substrate SUB1 to heat the components disposed on the first substrate SUB1 and may have a lower temperature than the first substrate SUB1 to cool the components disposed on the first substrate SUB1.

Referring to FIG. 8, each of the first temperature controller TU1, the second temperature controller TU2, and the third temperature controller TU3 may include metal.

The first temperature controller TU1, the second temperature controller TU2, and the third temperature controller TU3 may include metals having different thermal conductivity.

Therefore, even if the same heat is supplied from the plate PL contacting the first temperature controller TU1, the second temperature controller TU2, and the third temperature controller TU3, temperatures of the first temperature controller TU1, the second temperature controller TU2 and the third temperature controller TU3 may be different.

According to an embodiment, the metal included in the first temperature controller TU1 may have better thermal conductivity than the metal included in the second temperature controller TU2.

In addition, the metal included in the second temperature controller TU2 may have better thermal conductivity than the metal included in the third temperature controller TU3.

The metal according to an embodiment may include Ag, Cu, Mo, Ti, Cu, and the like.

When the same heat is supplied from the plate PL, the first temperature controller TU1 may have a temperature greater than the second temperature controller TU2 and the third temperature controller TU3, and the second temperature controller TU2 may have a temperature greater than the third temperature controller TU3.

Meanwhile, a gap between the first temperature controller TU1, the second temperature controller TU2, and the third temperature controller TU3 may be filled with an insulating material or an air.

Referring to FIG. 9, the first light emitting area LA1 may overlap the first temperature controller TU1.

The second light emitting area LA2 may overlap the second temperature controller TU2.

The third light emitting area LA3 may overlap the third temperature controller TU3.

The scattering layer SC overlapping the first light emitting area LA1 may be heated to a first temperature by the first temperature controller TU1.

The scattering layer SC overlapping the second light emitting area LA2 may be heated to a second temperature by the second temperature controller TU2.

The scattering layer SC overlapping the third light emitting area LA3 may be heated to a third temperature by the third temperature controller TU3.

For example, the first temperature, the second temperature, and the third temperature may be different from each other.

The non-light emitting areas NLA1, NLA2, and NLA3 positioned between the light emitting areas LA1, LA2, and LA3 do not contact the temperature controllers TU1, TU2, and TU3, and do not directly receive heat.

The scattering layer SC overlapping the non-light emitting areas NLA1, NLA2, and NLA3 may not overlap the temperature controllers TU1, TU2, and TU3.

The scattering layer SC overlapping the non-light emitting areas NLA1, NLA2, and NLA3 may have a fourth temperature.

The fourth temperature may be lower than the third temperature.

The temperature difference between the scattering layer SC overlapping the first light emitting area LA1 and the scattering layer SC overlapping the first non-light emitting area NLA1 is larger than the temperature difference between the scattering layer SC overlapping the second light emitting area LA2 and the scattering layer SC overlapping the second non-light emitting area NLA2.

The temperature difference between the scattering layer SC overlapping the second light emitting area LA2 and the scattering layer SC overlapping the second non-light emitting area NLA2 is larger than temperature difference between the scattering layer overlapping the third light emitting area LA3 and the scattering layer overlapping the third non-light emitting area NLA3.

The temperature difference according to an embodiment may be about 2 degrees (° C.) to about 100 degrees (° C.).

Due to this temperature difference, the scatterers included in the scattering layer SC may move.

Referring to the arrows in FIG. 9 and FIG. 10, the scatterer may move by a first movement amount between the scattering layer SC overlapping the first light emitting area LA1 and overlapping the first non-light emitting area NLA1 having the largest temperature difference.

Next, the scatterer may move by a second movement amount which is less than the first movement amount between the scattering layer SC overlapping the second light emitting area LA2 and overlapping the second non-light emitting area NLA2.

Finally, the scatterer may move by a third movement amount which is less than the second movement amount between the scattering layer SC overlapping the third light emitting area LA3 and overlapping the third non-light emitting area NLA3.

The amount of movement of the scatterer is indicated by the thickness of the arrow in FIG. 10.

The thicker the arrow, the greater the moving amount of the scatterer.

In one embodiment, the amount of scatterers included in the scattering layer SC overlapping the third light emitting area LA3 may be greater than the amount of scatterers included in the scattering layer SC overlapping the second light emitting area LA2.

The amount of scatterers included in the scattering layer SC overlapping the second light emitting area LA2 may be greater than the amount of scatterers included in the scattering layer SC overlapping the first light emitting area LA1.

In addition, among the scattering layers SC overlapping the non-light emitting areas NLA1, NLA2, and NLA3, the amount of scatterers included in the scattering layer SC overlapping the first non-light emitting area NLA1 is greater than the amount of scatterers included in the scattering layer SC overlapping the second non-light emitting area NLA2.

The amount of scatterers included in the scattering layer SC overlapping the second non-light emitting area NLA2 may be greater than the amount of scatterers included in the scattering layer SC overlapping the third non-light emitting area NLA3.

Although an embodiment in which the temperature control unit TU heats the scattering layer is illustrated, it is not limited thereto, and an embodiment in which the temperature control unit TU cools the scattering layer is also possible.

The scattering layer SC according to an embodiment may include a plurality of regions having different concentration of scatterers while continuously overlapping the entire surface of the first substrate SUB1.

Side luminance of the display device may be improved by providing scatterers having different densities depending on the color of emitted light.

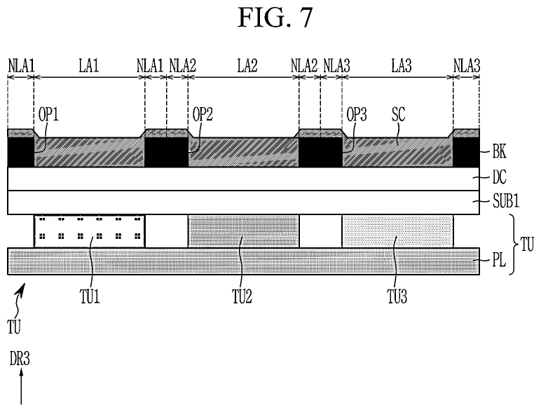

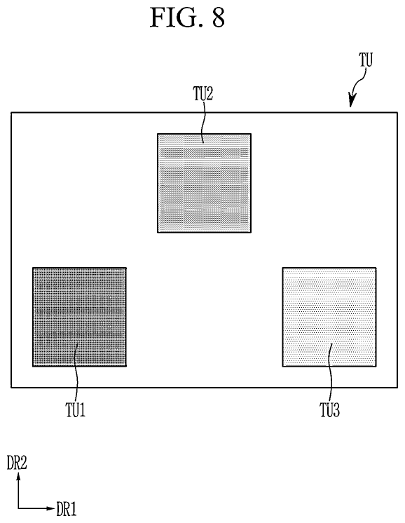

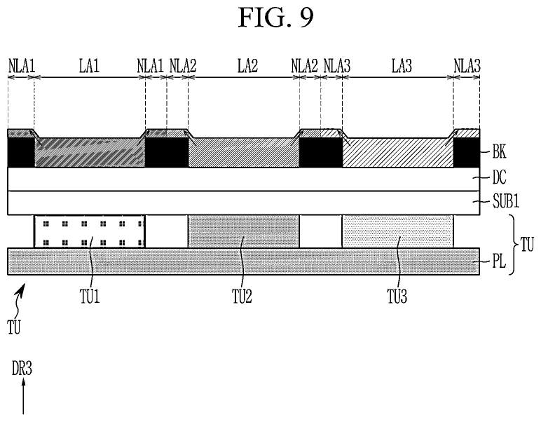

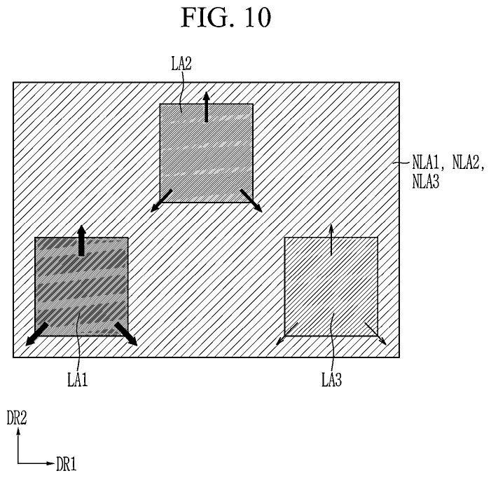

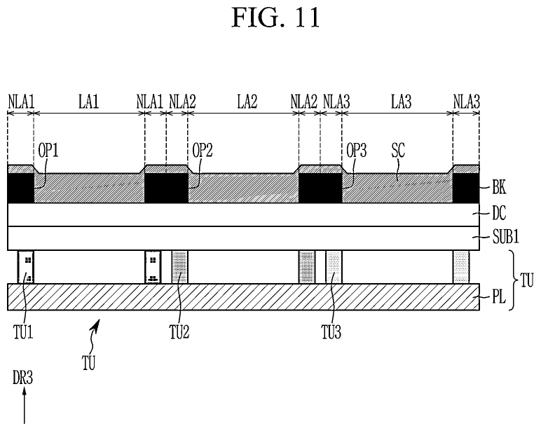

Hereinafter, a method of manufacturing a display device according to an embodiment will be described with reference to FIG. 11 to FIG. 14.

FIG. 11, FIG. 12, FIG. 13, and FIG. 14 are diagrams of a method of manufacturing a display device according to an embodiment.

Descriptions of the same components as those described above will be omitted.

Referring to FIG. 11, in a method of manufacturing a display device according to an embodiment, a display unit DC is formed on a first substrate SUB1.

The display unit DC may have the stacked structure previously described with reference to FIG. 3, and a detailed description thereof will be omitted below.

A partition wall (BK) is formed on the display unit (DC).

The partition wall BK may include a first opening OP1, a second opening OP2, and a third opening OP3 disposed in areas corresponding to the pixel openings.

The sizes of the first opening OP1, the second opening OP2, and the third opening OP3 may be different or the same.

A scattering layer SC including scatterers is formed on the partition wall BK.

The scattering layer SC may be formed on the entire surface of the first substrate SUB1.

The scattering layer SC may cover the top and side surfaces of the partition wall BK and fill each of the openings OP1, OP2, and OP3.

The scattering layer SC may be formed through a coating process, an inkjet process, or a photolithography process.

The method of forming the scattering layer SC may not be limited.

As shown in FIG. 11, the temperature control unit TU is provided on the rear surface of the first substrate SUB1. The temperature control unit TU which include a first temperature control unit TU1, a second temperature control unit TU2, and a third temperature control unit TU3 may overlap a first non-light emitting area NLA1, a second non-light emitting area NLA2, and a third non-light emitting area NLA3.

The temperature control unit TU may include a first temperature controller TU1, a second temperature controller TU2, a third temperature controller TU3, and a plate PL.

The plate PL may heat or cool the first temperature controller TU1, the second temperature controller TU2, and the third temperature controller TU3.

The plate PL may heat or cool the first temperature controller TU1, the second temperature controller TU2, and the third temperature controller TU3 to a predetermined temperature.

The first temperature controller TU1, the second temperature controller TU2, and the third temperature controller TU3 may have different temperatures or have the same temperature.

For example, the first temperature controller TU1, the second temperature controller TU2, and the third temperature controller TU3 have a higher temperature than the first substrate SUB1 and directly contact the first substrate SUB1. The plate may heat the components disposed on the first substrate SUB1 or may cool the components disposed on the first substrate SUB1.

Referring to FIG. 12, each of the first temperature controller TU1, the second temperature controller TU2, and the third temperature controller TU3 may include metal.

The first temperature controller TU1, the second temperature controller TU2, and the third temperature controller TU3 may include metals having different thermal conductivity.

Therefore, even if the same heat is supplied from the plate PL directly contacting the first temperature controller TU1, the second temperature controller TU2, and the third temperature controller TU3, the temperatures of the first temperature controller TU1 and the second temperature controller TU2 and the third temperature controller TU3 may be different from each other.

According to an embodiment, the metal included in the first temperature controller TU1 may have better thermal conductivity than the metal included in the second temperature controller TU2.

In addition, the metal included in the second temperature controller TU2 may have higher thermal conductivity than the metal included in the third temperature controller TU3.

Accordingly, when the same heat is supplied from the plate PL, the temperature of the first temperature controller TU1 is higher than that of the second temperature controller TU2 and the temperature of the second temperature controller TU2 is higher than that of the third temperature controller TU3.

Meanwhile, a gap between the first temperature controller TU1, the second temperature controller TU2, and the third temperature controller TU3 may be filled with an insulating material or an air.

Referring to FIG. 13, according to the temperature control unit TU in contact with the first substrate SUB1, the first non-light emitting area NLA1 may overlap the first temperature controller TU1.

The second non-light emitting area NLA2 may overlap the second temperature controller TU2.

The third non-light emitting area NLA3 may overlap the third temperature controller TU3.

The scattering layer SC overlapping the first non-light emitting area NLA1 may be heated to a first temperature, the scattering layer SC overlapping the second non-light emitting area NLA2 may be heated to a second temperature lower than the first temperature, and the scattering layer SC overlapping the third non-light emitting area NLA3 may be heated to a third temperature lower than the second temperature.

A metal included in each of the first temperature controller TU1, the second temperature controller TU2, and the third temperature controller TU3 may not overlap the light emitting areas LA1, LA2, and LA3.

Each of the first temperature controller TU1, the second temperature controller TU2, and the third temperature controller TU3 may include an opening disposed in areas corresponding to the emitting areas LA1, LA2, and LA3.

An insulating material may be filled in the opening, or the opening may be an empty space in which an air gap is located.

The light emitting areas LA1, LA2, and LA3 do not overlap the metal of the temperature controllers TU1, TU2, and TU3 that transfer heat, and do not directly receive heat.

The scattering layer SC overlapping the light emitting area LA may have a fourth temperature.

The fourth temperature may be lower than the third temperature.

A first temperature difference between the scattering layer SC overlapping the first non-light emitting area NLA1 and the scattering layer SC overlapping the first light emitting area LA1 is greater than a second temperature difference between the scattering layer SC overlapping the second non-light emitting area NLA2 and the scattering layer SC overlapping the second light emitting area LA2.

The second temperature difference between the scattering layer SC overlapping the second non-light emitting area NLA2 and the scattering layer SC overlapping the second light emitting area LA2 is greater than a third temperature difference between the scattering layer SC overlapping the third non-light emitting area NLA3 and the scattering layer SC overlapping the third light emitting area LA3.

Due to this temperature difference, the scatterers included in the scattering layer SC may move.

The greater the temperature difference, the greater the amount of moving scatterers.

Referring to FIG. 13 and FIG. 14, the amount of the scatterers moving from the first non-light emitting area NLA1 to the first light-emitting area LA1 may be greater than the amount of scatterers moving from the second light-emitting area NLA2 to the second light-emitting area LA2.

The amount of scattering material moving from the second non-light emitting area NLA2 to the second light emitting area LA2 may be greater than the amount of scatterers moving from the third non-light emitting area NLA3 to the third light emitting area LA3.

The amount of moving scatterers is indicated by the thickness of the arrow in FIG. 14.

A scattering layer SC overlaps the first light emitting area LA1, a scattering layer SC overlaps the second light emitting area LA2, and a scattering layer SC overlaps the third light emitting area LA3, respectively. The amount of scatterers included in the scattering layer overlapping the first light emitting area LA1 is greater than that included in the scattering layer overlapping the second light emitting area LA2, and the amount of scatterers included in the scattering layer overlapping the second light emitting area LA2 is greater than that included in the scattering layer overlapping the third light emitting area LA3.

The amount of scatterers moves from the scattering layer SC overlapping the first non-light emitting area NLA1 to the first light-emitting area LA1 is greater than that moves from the scattering layer overlapping the second non-light emitting area NLA2 SC to the second light emitting area LA2.

The scattering layer SC according to an embodiment may include a plurality of regions having different concentration of scatterers while continuously overlapping the entire surface of the substrate SUB1.

Side luminance of the display device may be improved by providing scatterers having different concentration according to regions according to the color of emitted light.

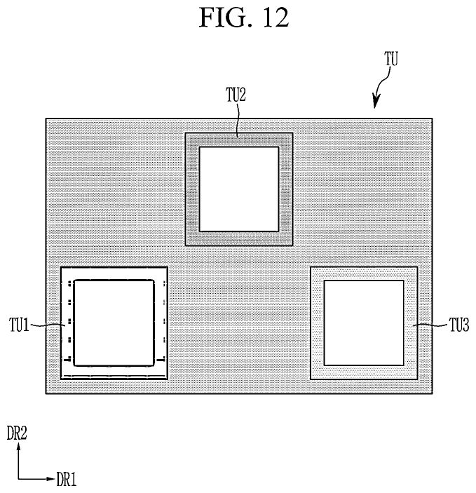

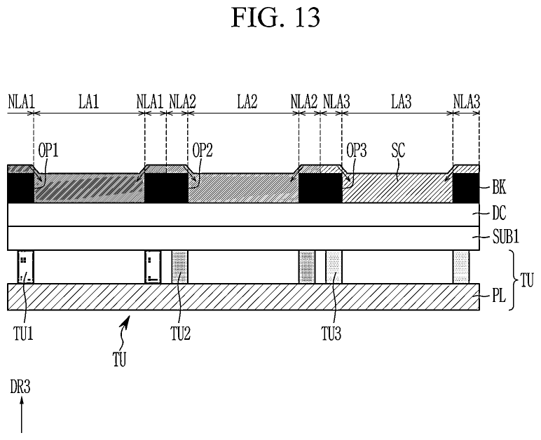

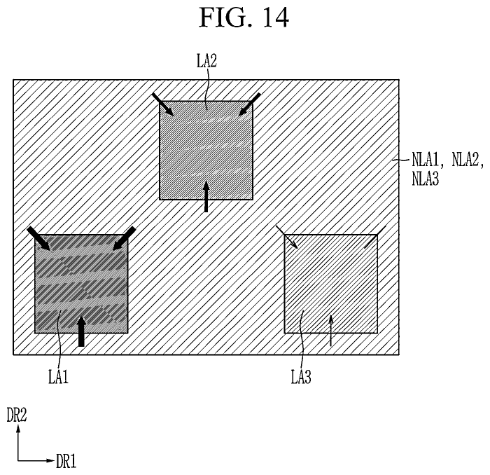

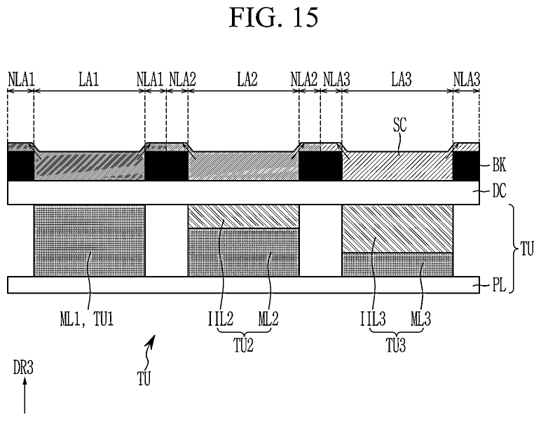

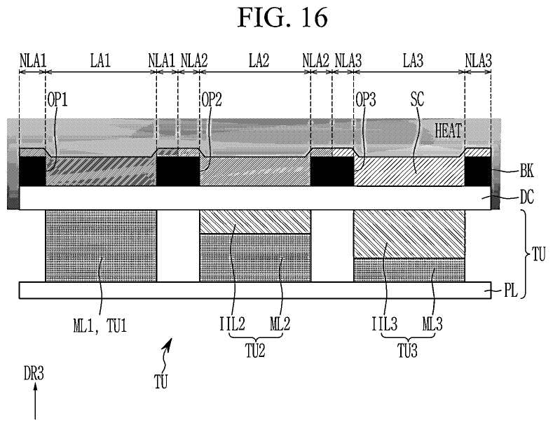

Hereinafter, a method of manufacturing a display device according to another embodiment will be described with reference to FIG. 15 and FIG. 16.

FIG. 15 and FIG. 16 are diagrams of a manufacturing method of a display device according to an embodiment.

First, as shown in FIG. 15, in the manufacturing method of the display device according to an embodiment, a partition wall BK is formed on the display unit DC.

A scattering layer SC including scatterer is formed on the partition wall BK.

The scattering layer SC may be formed on the entire surface of the display unit DC.

The scattering layer SC may cover the top and side surfaces of the partition wall BK.

The scattering layer SC may be formed through a coating process, an inkjet process, or a photolithography process.

A method of forming the scattering layer SC may not be limited.

Then, the temperature control unit TU is provided on a plate PL.

Although the present specification shows a configuration in which the temperature control unit TU directly contacts the rear surface of the display unit DC for convenience, it may directly contact the rear surface of the first substrate SUB1 as described above.

The temperature control unit TU may include a first temperature controller TU1, a second temperature controller TU2, a third temperature controller TU3, and the plate PL.

The first temperature controller TU1, the second temperature controller TU2, and the third temperature controller TU3 may have different temperatures or have the same temperature.

For example, the first temperature controller TU1, the second temperature controller TU2, and the third temperature controller TU3 have a higher temperature than the display unit DC and directly contacts the display unit DC. Components disposed on the display unit DC may be heated by the temperature controller TU, or the components disposed on the display unit DC may be cooled by the temperature controller TU.

The first temperature controller TU1, the second temperature controller TU2, and the third temperature controller TU3 may include metal layers ML1, ML2, and ML3 including the same metal.

However, the first temperature controller TU1, the second temperature controller TU2, and the third temperature controller TU3 may include metal layers ML1, ML2, and ML3 having different thicknesses.

The thickness of the metal layer included in the first temperature controller TU1 may be greater than that included in the second temperature controller TU2. The thickness of the metal layer included in the second temperature controller TU3 may be greater than that included in the third temperature controller TU3.

Also, the second temperature controller TU2, and the third temperature controller TU3 may include insulating layers IIL2 and IIL3 having different thicknesses.

The first temperature controller TU1 does not include an insulating layer, the second temperature controller TU2 includes a second insulating layer IIL2 having a first thickness, and the third temperature controller TU3 includes a third insulating layer IIL3 having a second thickness.

The first thickness may be less than the second thickness.

The second insulating layer IIL2 and the third insulating layer IIL3 may include a heat insulating material, for example, an Si-based compound, a carbon-based compound, or a polymer-based compound.

According to an embodiment, the first temperature controller TU1 includes the first metal layer ML1 disposed on the plate PL. And the second temperature controller TU2 includes the second metal layer ML2 disposed on the plate PL and an insulating layer IIL2 disposed on the second metal layer ML2. The third temperature controller TU3 includes a third metal layer ML3 disposed on the plate PL and a third insulating layer IIL3 disposed on the third metal layer ML3.

Even if the same heat is supplied from the plate PL connected to the first temperature controller TU1, the second temperature controller TU2, and the third temperature controller TU3, temperatures provided by the first temperature controller TU1, the second temperature controller TU2 and the third temperature controller TU3 may be different.

When the same temperature is provided from the plate PL, the temperature provided by the first temperature controller TU1 is greater than that provided by the second temperature controller TU2, and the temperature provided by the second temperature controller TU2 is greater than that provided by the third temperature controller TU3.

According to the temperature control unit TU contacting the display unit DC, the first light emitting area LA1 may overlap the first temperature controller TU1.

The second light emitting area LA2 may overlap the second temperature controller TU2.

The third light emitting area LA3 may overlap the third temperature controller TU3.

The scattering layer SC overlapping the first light emitting area LA1 may be heated to a first temperature by the first temperature controller TU1.

The scattering layer SC overlapping the second light emitting area LA2 may be heated to a second temperature which is lower than the first temperature by the second temperature controller TU2.

The scattering layer SC overlapping the third light emitting area LA3 may be heated to a third temperature which is lower than the second temperature by the third temperature controller TU3.

The non-light emitting areas NLA1, NLA2, and NLA3 positioned between the light emitting areas LA1, LA2, and LA3 do not overlap the temperature controllers TU1, TU2, and TU3, and do not directly receive heat.

The scattering layer SC overlapping the non-light emitting areas NLA1, NLA2, and NLA3 may have a fourth temperature.

The fourth temperature may be lower than the third temperature.

The temperature difference between the scattering layer SC overlapping the first light emitting area LA1 and the scattering layer SC overlapping the first non-light emitting area NLA1 is greater than the temperature difference between the scattering layer SC overlapping the second light emitting area LA2 and the scattering layer SC overlapping the second non-light emitting area NLA2.

The temperature difference between the scattering layer SC overlapping the second light emitting area LA2 and the scattering layer SC overlapping the second non-emitting area NLA2 is greater than the temperature difference between the scattering layer SC overlapping the third light emitting area LA3 and the scattering layer SC overlapping the third non-light emitting area NLA3.

Due to this temperature difference, the scatterers included in the scattering layer SC may move.

In FIG. 16, when the difference between the first temperature and the fourth temperature, the difference between the second temperature and the fourth temperature, and the difference between the third temperature and the fourth temperature are not large enough to cause a movement of the scatterers, heat or light is applied to the scattering layer SC, and an additional thermal gradient can be induced.

For example, light in the near-infrared wavelength range may be supplied to the scattering layer SC at 4000 Mw for less than 1 minute.

According to this, the scatterer may move from the first light emitting area LA1 to the first non-light emitting area NLA1 by a first amount.

Next, the scatterer may move from the scattering layer SC overlapping the second light emitting area LA2 to the second non-light emitting area NLA2 by a second amount.

Finally, the scatterer may move from the scattering layer SC overlapping the third light emitting area LA3 to the third non-light emitting area NLA3 by a third amount.

The first amount may be greater than the second amount, the second amount may be greater than the third amount.

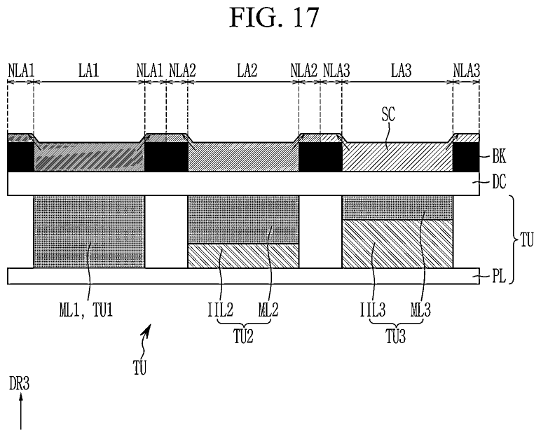

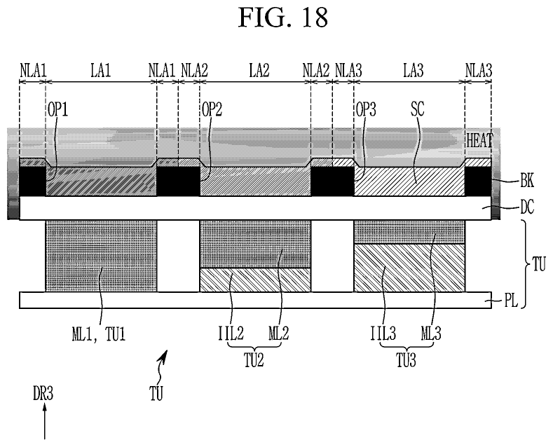

Hereinafter, a method of manufacturing a display device according to another embodiment will be described with reference to FIG. 17 and FIG. 18.

FIG. 17 and FIG. 18 are diagrams of a method of manufacturing a display device according to an embodiment.

The embodiments of FIG. 17 and FIG. 18 may be the same as the embodiments of FIG. 15 and FIG. 16 except the location of the metal layer and the insulating layer. The second temperature controller TU2 includes the second insulating layer IIL2 positioned between the plate PL and the second metal layer ML2. The third temperature controller TU3 includes the third insulating layer IIL3 positioned between the plate PL and the third metal layer ML3.

Contents except for this may be the same as described above.

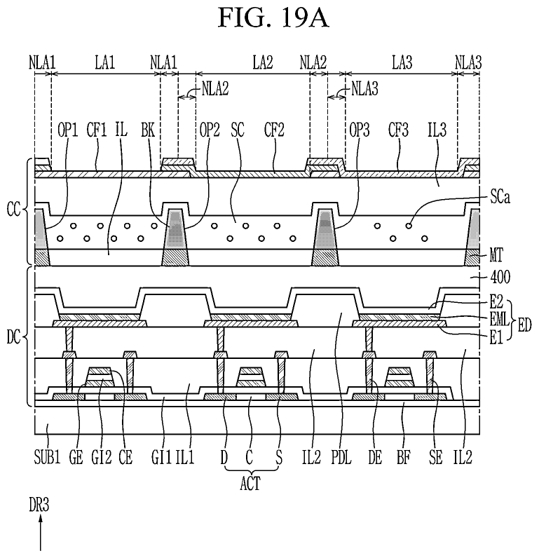

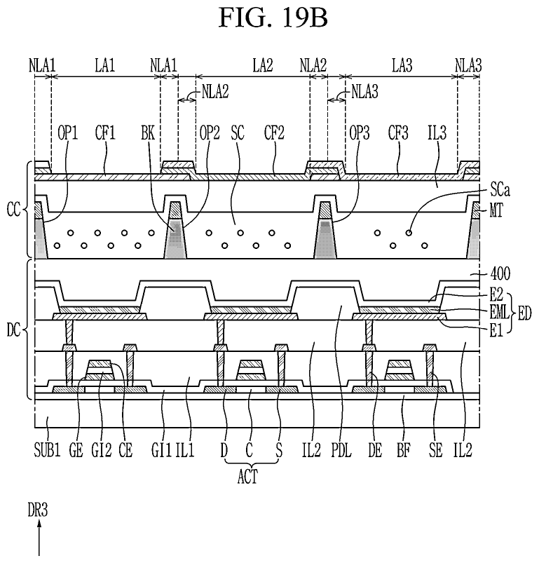

Hereinafter, a structure of a display device according to another embodiment will be described with reference to FIG. 19A and FIG. 19B.

FIG. 19A and FIG. 19B are schematic cross-sectional views of a display panel according to another embodiment.

Descriptions of components identical to those described above will be omitted.

First, referring to FIG. 19A, a display device according to an embodiment may include a display unit DC and a color conversion unit CC disposed on the display unit DC.

The color conversion unit CC may include an auxiliary metal layer MT positioned on the display unit DC.

The auxiliary metal layer MT may be in a floating state which is not connected to a separate voltage source.

The auxiliary metal layer MT may overlap the partition wall BK, which will be described later.

The auxiliary metal layer MT may be positioned between the partition wall BK and the pixel defining layer PDL.

The thickness of the auxiliary metal layer MT may be about 20 micrometers or less, and the width of the auxiliary metal layer MT may be about 80 micrometers or less.

When the auxiliary metal layer MT overlaps the partition wall BK, the metal constituting the auxiliary metal layer MT may have a transmittance of 90% or less.

Alternatively, although not shown, when the auxiliary metal layer MT overlaps the light emitting area, the transmittance may be 90% or more.

The auxiliary metal layer MT may include Al, Ag, or Cu.

In addition, the auxiliary metal layer MT may further include at least one of silicon carbide, nichrome (Ni—Cr), tungsten, quartz, TiO₂, and SiO₂ to absorb near infrared rays.

An insulating layer IL may be positioned between adjacent auxiliary metal layers MT.

The insulating layer IL may be an inorganic material or an organic material.

This specification illustrates an embodiment where an insulating layer IL is located between adjacent auxiliary metal layers MT, but is not limited to this, and the insulating layer IL can be provided in a form that completely covers multiple auxiliary metal layers MT.

That is, the insulating layer IL may be positioned to cover the upper surfaces of the plurality of auxiliary metal layers MT.

The partition wall BK may be positioned on the auxiliary metal layer MT.

The scattering layer SC may be positioned on the partition wall BK and the insulating layer IL.

The scattering layer SC may overlap the entire surface of the first substrate SUB1.

The scattering layer SC may continuously overlap the first substrate SUB1.

The scattering layer SC may cover the top and side surfaces of the partition wall BK, and may be positioned in the openings OP1, OP2, and OP3.

A third insulating layer IL3 may be positioned on the scattering layer SC, and the color filters CF1, CF2, and CF3 may be positioned on the third insulating layer IL3.

Referring next to FIG. 19B, a display device according to an embodiment may include a display unit DC and a color conversion unit CC located on the display unit DC.

The color conversion unit CC may include an auxiliary metal layer MT positioned on the partition wall BK.

The auxiliary metal layer MT may be in a floating state which is not connected to a separate voltage source.

A portion of the scattering layer SC may cover an upper surface of the auxiliary metal layer MT.

The third insulating layer IL3 may be positioned on the scattering layer SC.

The color filters CF1, CF2, and CF3 may be positioned on the third insulating layer IL3.

Although the present specification shows the display devices of FIG. 19A and FIG. 19B in which an auxiliary metal layer is added in the embodiment of FIG. 5, the auxiliary metal layer is not limited thereto and may be applied to the embodiments of FIG. 3 and FIG. 4 as well.

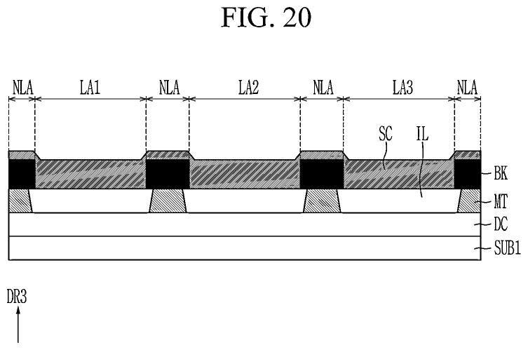

Hereinafter, a manufacturing method of a display device according to an embodiment will be described with reference to FIG. 20 to FIG. 23.

FIG. 20, FIG. 21, FIG. 22, and FIG. 23 are diagrams of a method of manufacturing a display device according to another embodiment.

Descriptions of the same components as those described above will be omitted.

Referring to FIG. 20, the display device according to an embodiment may include an auxiliary metal layer MT positioned on the display unit DC.

The auxiliary metal layer MT according to an embodiment may be in a floating state which is not connected to a separate voltage source.

A detailed structure is described with reference to FIG. 19A, and hereinafter, FIG. 20 to FIG. 23 are schematic diagrams showing only some components.

As shown in FIG. 21, the auxiliary metal layer MT may have different widths.

For example, the auxiliary metal layer MT1 surrounding the first light emitting area LA1 has a first width, the auxiliary metal layer MT2 surrounding the second light emitting area LA2 has a second width less than the first width, the auxiliary metal layer MT3 surrounding the third light emitting area LA3 may have a third width less than the second width.

In FIG. 22 and FIG. 23, the widths of the auxiliary metal layers MT surrounding the light emitting areas LA1, LA2, and LA3 may be different.

Referring to FIG. 22, a plate PL is provided under the display unit DC under the first substrate SUB1.

The plate PL may supply heat to the display panel according to an embodiment.

In particular, the plate PL may supply heat to the auxiliary metal layer MT.

When the same heat is provided to the auxiliary metal layer MT, the first auxiliary metal layer MT1 having a relatively large width has the highest temperature, and the second auxiliary metal layer MT2 sequentially has the next highest temperature. Finally, the third auxiliary metal layer MT3 may have a relatively low temperature.

The temperature difference between the scattering layer SC overlapping the first light emitting area LA1 and the scattering layer SC overlapping the non-light emitting area NLA is larger than the temperature difference between the scattering layer SC overlapping the second light emitting area LA2 and the scattering layer SC overlapping the non-light emitting area NLA due to the difference in width of the auxiliary metal layer MT1 and MT2.

The temperature difference between the scattering layer SC overlapping the second light emitting area LA2 and the scattering layer SC overlapping the non-emitting area NLA is larger than the temperature difference between the scattering layer SC overlapping the third light emitting area LA3 and the scattering layer SC overlapping the non-emitting area NLA due to the difference in width of the auxiliary metal layer MT2 and MT3.

Due to this temperature difference, the scatterers included in the scattering layer SC may move.

The movement amount of the scatterers may be greatest between the scattering layer SC overlapping the first light emitting area LA1 and the non-light emitting area NLA having the largest temperature difference.

Next, the scatterers may be moved between the second light emitting area LA2 and the scattering layer SC overlapping the non-light emitting area NLA.

Finally, a relatively small amount of scatterers may be moved between the scattering layer SC overlapping the third light emitting area LA3 and the non-light emitting area NLA.

In addition, as shown in FIG. 23, when the temperature difference between the light-emitting areas LA1, LA2, and LA3, and the non-light emitting area NLA is not large, heat or light is applied to the scattering layer SC to generate additional movement of scatterers.

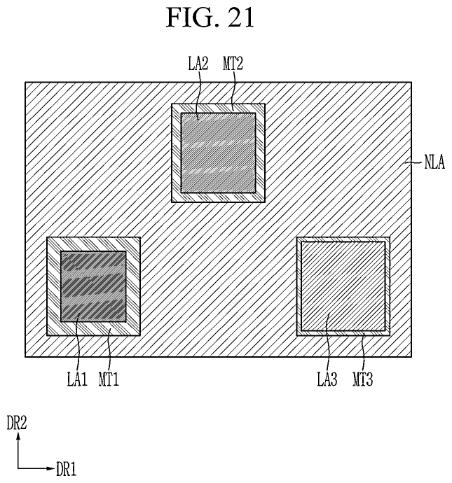

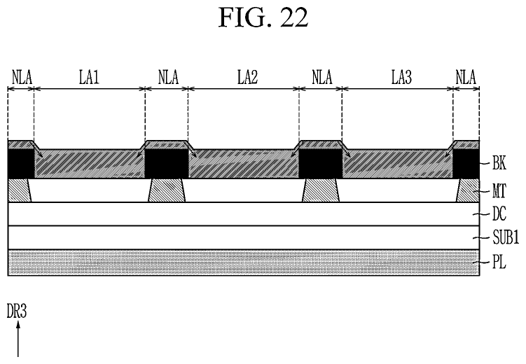

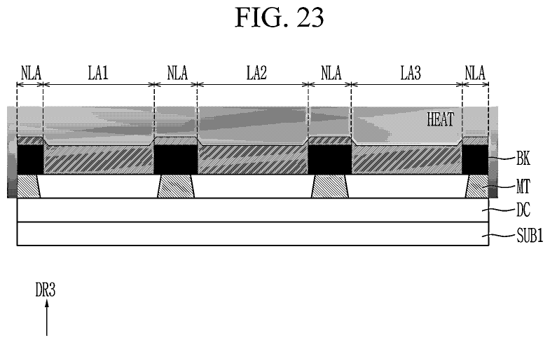

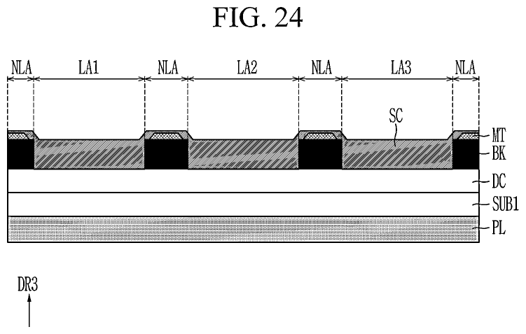

A manufacturing method of a display device according to another embodiment will be described with reference to FIG. 24 and FIG. 25.

FIG. 24 and FIG. 25 are diagrams of a method of manufacturing a display device according to another embodiment.

Descriptions of the same components as those described above will be omitted.

Referring to FIG. 24, the display device according to an embodiment may include the auxiliary metal layer MT positioned on the partition wall BK.

The auxiliary metal layer MT according to an embodiment may be in a floating state which is not connected to a separate voltage source.

The specific structure is described with reference to FIG. 19B, FIG. 24, and FIG. 25 are schematic diagrams showing only some components.

As shown in FIG. 21 above, the auxiliary metal layer MT may have different widths.

For example, the auxiliary metal layer MT1 surrounding the first light emitting area LA1 has a first width, the auxiliary metal layer MT2 surrounding the second light emitting area LA2 has a second width less than the first width, and the auxiliary metal layer MT3 surrounding the third light emitting area LA3 may have a third width less than the second width.

Referring to FIG. 24, the plate PL is provided below the first substrate SUB1 and the display unit DC.

The plate PL may supply heat to the display panel according to an embodiment.

The plate PL may provide heat to the auxiliary metal layer MT.

When the same heat is provided to the auxiliary metal layer MT, the first auxiliary metal layer MT1 having a relatively large width has the first temperature, and the second auxiliary metal layer MT2 has the second temperature lower than the first temperature. Finally, the third auxiliary metal layer MT3 may have a third temperature lower than the second temperature.

The temperature difference between the scattering layer SC overlapping the first light emitting area LA1 and the scattering layer SC overlapping the non-light emitting area NLA is larger than the temperature difference between the scattering layer SC overlapping the second light-emitting area LA2 and the scattering layer SC overlapping the non-light emitting area NLA due to the auxiliary metal layer MT1 and MT2 having different widths.

The temperature difference between the scattering layer SC overlapping the second light emitting area LA2 and the scattering layer SC overlapping the non-emitting area NLA is greater than the temperature difference between the scattering layer SC overlapping the third light emitting area LA3 and the scattering layer SC overlapping the non-light emitting area NLA due to the auxiliary metal layer MT2 and MT3 having different widths.

Due to this temperature difference, the scatterers included in the scattering layer SC may move.

The movement amount of the scatterers may be greatest between the scattering layer SC overlapping the first light emitting area LA1 and the non-light emitting area NLA having the largest temperature difference.

Next, the scatterers may be moved between the second light emitting area LA2 and the scattering layer SC overlapping the non-light emitting area NLA.

Finally, a relatively small amount of scatterers may be moved between the scattering layer SC overlapping the third light emitting area LA3 and the non-light emitting area NLA.

In addition, when the temperature difference between the light-emitting areas LA1, LA2, and LA3, and the non-light emitting area NLA is not large, heat or light is applied to the scattering layer SC as shown in FIG. 25, so the additional movement of scatterers can be induced.

Hereinafter, various embodiments of the scatterers included in the aforementioned scattering layer will be described.

FIG. 26 is a schematic cross-sectional view of a scatterer according to an embodiment.

As shown in FIG. 26A, the scatterer SCa may have a core and shell structure which includes a core SCa1 selected from the group consisting of SiO₂, Fe₂O₃, BaSO₄, Al₂O₃, ZnO, ZrO₂, and TiO₂, and a shell MTL including metal and surrounding the core.

Alternatively, as shown in FIG. 26B, the scatterer SCa may have a core and shell structure which includes a metal core MTL and a shell SCa1 c which includes one or more layer selected from a group consisting of SiO₂, Fe₂O₃, BaSO₄, Al₂O₃, ZnO, ZrO₂, and TiO₂.

Alternatively, as shown in FIG. 26C, the scatterer SCa may have a mixture of metal and at least one scatterer selected from the group consisting of SiO₂, Fe₂O₃, BaSO₄, Al₂O₃, ZnO, ZrO₂, and TiO₂.

In addition, the scatterer SCa in which the scatterer and the metal are mixed may be transformed into various shapes as shown in FIG. 26D.

When the scatterer SCa shown in FIG. 26A, FIG. 26B, FIG. 26C, and FIG. 26D is provided in the scattering layer SC, conduction of heat provided from the plate may be accelerated.

Since the movement of the scatterer SCa is easy, it may be easy to provide scattering layers having different concentration for each area.

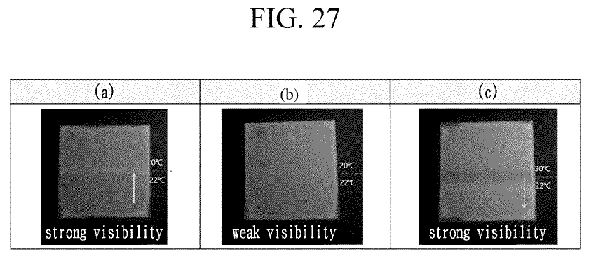

FIG. 27 is an image illustrating the movement of the scatterer according to the temperature difference.

FIG. 27(a) is an image in which a scatterer moves to the extent that it is strongly visible when a plate with 0 degrees (° C.) is attached to a substrate with 22 degrees (° C.).

FIG. 27(b) is an image showing that the movement of the scatterer is insignificant when a plate with 20 degrees (° C.) is attached to a substrate with 22 degrees (° C.).

FIG. 27(c) is an image showing that scatterers move strongly when a plate with 30 degrees (° C.) is attached to a substrate with 22 degrees (° C.).

That is, it was confirmed that the temperature gradient between the substrate and the plate accelerates the movement of the scatterer.

Although the embodiments of the present inventive concept have been described in detail above, the scope of the present inventive concept is not limited thereto, and various modifications and improvements made by those skilled in the art using the basic concepts of the present inventive concept defined in the following claims are also included in the scope of the present inventive concept.

What is claimed is:

1. A display device, comprising:
a substrate including a first light emitting area, a second light emitting area, and a third light emitting area;
a transistor disposed on the substrate;
a light emitting element connected to the transistor;
an encapsulation layer disposed on the light emitting element;
a partition wall disposed on the encapsulation layer; and
a scattering layer disposed on the partition wall,
wherein the scattering layer is continuously disposed on an entire surface of the substrate, and
wherein the scattering layer includes scatterers having different concentration in the first light emitting area, the second light emitting area, and the third light emitting area.

2. The display device of claim 1, wherein:
the substrate further includes a first non-light emitting area, a second non-light emitting area, and a third non-light emitting area.

3. The display device of claim 2, wherein:
the scattering layer overlaps the first non-light emitting area, the second non-light emitting area, and the third non-light emitting area, and includes scatterers having different concentration in each area.

4. The display device of claim 3, wherein:
a concentration of scatterers included in the scattering layer overlapping the first light emitting area is greater than that included in the scattering layer overlapping the second light emitting area, and the concentration of scatters included in the scattering layer overlapping the second light emitting area is greater than that included in the scattering layer overlapping the third light emitting area.

5. The display device of claim 4, wherein:
a concentration of scatterers included in a scattering layer overlapping the first non-light emitting area is less than that included in a scattering layer overlapping the second non-light emitting area, and the concentration of the scatters in the scattering layer overlapping the second non-light emitting area is less than that included in a scattering layer overlapping the third non-light emitting area.

6. The display device of claim 1, wherein:
the scattering layer covers side surfaces and one surface of the partition wall and fills an opening of the partition wall.

7. The display device of claim 1, further comprising:
a color filter disposed on the scattering layer,
wherein the color filter includes:
a first color filter overlapping the first light emitting area,
a second color filter overlapping the second light emitting area, and
a third color filter overlapping the third light emitting area.

8. The display device of claim 1, wherein:
the light emitting element emits white light, and
the light emitting element has a tandem structure.

9. A method of manufacturing a display device, comprising:
forming a display unit on a front side of a substrate;
forming a partition wall on the display unit;
forming a scattering layer on the partition wall;
providing a temperature control unit on a rear side of the substrate; and
changing the temperature of the scattering layer through the temperature control unit, and
where scatterers are included in the scattering layer and the scatters move in the step of changing the temperature of the scattering layer.

10. The method of manufacturing a display device of claim 9, wherein:
the substrate includes a first light emitting area, a second light emitting area, and a third light emitting area.

11. The method of manufacturing a display device of claim 10, wherein:
the temperature control unit comprises:
a first temperature controller overlapping the first light emitting area,
a second temperature controller overlapping the second light emitting area, and
a third temperature controller overlapping the third light emitting area, and
wherein the first temperature controller, the second temperature controller, and the third temperature controller have different temperatures.

12. The method of manufacturing a display device of claim 11, wherein:
the first temperature controller includes a first metal,
the second temperature controller includes a second metal,
the third temperature controller includes a third metal, and
thermal conductivity of the first metal, the second metal, and the third metal are different from one another.

13. The method of manufacturing a display device of claim 12, wherein:
the scattering layer overlapping the first temperature controller is heated to a first temperature,
the scattering layer overlapping the second temperature controller is heated to a second temperature lower than the first temperature,
the scattering layer overlapping the third temperature controller is heated to a third temperature lower than the second temperature.

14. The method of manufacturing a display device of claim 13, wherein:
the scatterer included in the scattering layer moves from a high-temperature area to a low-temperature area.

15. The method of manufacturing a display device of claim 14, wherein:
amount of movement of the scatterers included in the scattering layer increases as a temperature difference with an adjacent region increases.

16. The method of manufacturing a display device of claim 11, wherein:
the first temperature controller includes a first metal layer,
the second temperature controller includes a second metal layer and a second insulating layer, and
the third temperature controller includes a third metal layer and a third insulating layer.

17. The method of manufacturing a display device of claim 16, wherein:
a thickness of the first metal layer is greater than that of the second metal layer and the thickness of the second metal layer is greater than that of the third metal layer, and
the first metal layer, the second metal layer, and the third metal layer include the same metal.

18. The method of manufacturing a display device of claim 16, wherein:
a thickness of the second insulating layer is less than that of the third insulating layer.

19. The method of manufacturing a display device of claim 9, wherein:
the substrate comprises:
a first non-light emitting area disposed adjacent to the first light emitting area,
a second non-light emitting area disposed adjacent to the second light emitting area, and
a third non-light emitting area disposed adjacent to the third light emitting area,
the temperature control unit comprises:
a first temperature controller overlapping the first non-light emitting area,
a second temperature controller overlapping the second non-light emitting area, and
a third temperature controller overlapping the third non-light emitting area, and
the first temperature controller, the second temperature controller, and the third temperature controller have different temperatures.

20. The method of manufacturing a display device of claim 19, wherein:
the first temperature controller includes a first metal,
the second temperature controller includes a second metal,
the third temperature controller includes a third metal, and
thermal conductivity of the first metal is greater than that of the second metal and the thermal conductivity of the second metal is greater than that of the third metal.
